(19) United States
(12) Patent Application Publication
(10) Pub. No.: US 2025/0183064 A1
(43) Pub. Date: Jun. 5, 2025

(54) SUBSTRATE PREHEATING MODULE, A DEVICE PROCESSING ASSEMBLY WITH A SUBSTRATE PREHEATING FUNCTION AND THE METHOD OF THE SAME

(71) Applicant: ASM IP Holding B.V., Almere (NL)

(72) Inventors: Mandar Vijay Deshpande, Phoenix, AZ (US); Samer Banna, Phoenix, AZ (US)

(21) Appl. No.: 18/961,145

(22) Filed: Nov. 26, 2024

Related U.S. Application Data
(60) Provisional application No. 63/604,554, filed on Nov. 30, 2023.

(51) Int. Cl. H01L 21/67; H01L 21/324

(52) U.S. Cl. CPC H01L 21/67109; H01L 21/324

(57) ABSTRACT

A substrate preheating module is presented. According to an embodiment of the present disclosure, the module comprising a chamber configured to receive more than one substrates from an equipment front end module (EFEM), a first opening disposed on a wall of the chamber adjacent to the EFEM, a gas inlet configured to deliver a gas from an outer gas source into the chamber, a first valve disposed at the gas inlet and configured to control the input of the gas into the chamber, an exhaust vent configured to pump out the gas from the chamber, a second valve disposed at the exhaust vent and configured to control the exhaust of the gas from the chamber and a heater configured to heat the gas in the chamber. The module may further comprise a controller to control the valves and heater.

### CROSS-REFERENCE TO RELATED APPLICATION(S)

This Application claims the benefit of U.S. Provisional Application 63/604,554 filed on Nov. 30, 2023, the entire contents of which are incorporated herein by reference.

### FIELD OF INVENTION

The present disclosure relates to a device processing assembly, particularly to a substrate preheating module, a substrate processing assembly with a substrate preheating function and a method to operate the processing assembly.

### BACKGROUND OF THE DISCLOSURE

Many semiconductor deposition process modules require heating of the silicon wafer (substrate) to achieve the required process temperature. This heating step adds overhead to the processing time and hence lowers the chamber throughput.

Preheating of the substrate prior to introduction into the process module can help reduce the time spent in the chamber and improve the overall system throughput.

Therefore, the present disclosure presents a substrate preheating module and a substrate processing assembly, i.e., equipment front end module (EFEM), with one or more substrate preheating modules attached to one side and a method how to operate the EFEM for preheating substrates.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a substrate preheating module, comprising a chamber configured to receive more than one substrates from an equipment front end module (EFEM); a first opening disposed on a wall of the chamber adjacent to the EFEM; a gas inlet configured to deliver a first gas from an outer gas source into the chamber; a first valve disposed at the gas inlet and configured to control the input of the first gas into the chamber; an exhaust vent configured to pump out the first gas from the chamber; a second valve disposed at the exhaust vent and configured to control the exhaust of the first gas from the chamber; and a heater configured to heat the first gas in the chamber.

In at least one aspect, the substrate preheating module further comprising: a controller electrically coupled to the chamber, the first valve, the second valve and the heater and configured to control an opening/closing of the first and second valve and a turning on/off of the heater.

In at least one aspect, the substrate preheating module further comprising: a baffle disposed at a mouth of the gas inlet.

In at least one aspect, the substrate preheating module further comprising: a second opening disposed at a wall of the chamber opposite side of the first opening for maintenance.

In at least one aspect, the heater comprises at least two heating units and the heating units are disposed at least on a upside wall and on a downside wall of the chamber.

In at least one aspect, the heater comprises an ultra-violet (UV) lamps or an excimer laser.

In at least one aspect, the first gas comprises one of nitrogen (N₂), argon (Ar), helium (He), or a mixture thereof.

In at least one aspect, the EFEM is configured to move and provide substrates for preheating and processing.

In accordance with another embodiment there may be provided, a device processing assembly, comprising: an equipment front end module (EFEM) including an equipment front end module chamber having one or more interface openings and a robot arm for moving substrates; a load lock chamber; a plurality of processing chambers configured to process substrates; and one or more substrate preheating modules attached to a side of the EFEM, the one or more substrate preheating modules each comprising: a chamber configured to receive more than one substrates from an EFEM; a first opening disposed on a wall of the chamber adjacent to the EFEM; a gas inlet configured to deliver a first gas from an outer gas source into the chamber; a first valve disposed at the gas inlet and configured to control the input of the first gas into the chamber; an exhaust vent configured to pump out the first gas from the chamber; a second valve disposed at the exhaust vent and configured to control the exhaust of the first gas from the chamber; and a heater configured to heat the first gas in the chamber.

In at least one aspect, the one or more substrate preheating modules each further comprising: a controller electrically coupled to the substrate preheating module and configured to control an opening/closing of the first and second valve and a turning on/off of the heater.

In at least one aspect, the one or more substrate preheating modules each further comprising: a baffle disposed at a mouth of the gas inlet.

In at least one aspect, the one or more substrate preheating modules each further comprising: a second opening disposed at a wall of the chamber opposite side of the first opening.

In at least one aspect, the heater comprises at least two heating units and the heating units are disposed at least on an upside wall and on a downside wall of the chamber.

In at least one aspect, the heater in each of the one or more substrate preheating modules comprises ultra-violet (UV) lamps or an excimer laser.

In at least one aspect, the first gas comprises one of nitrogen (N₂), argon (Ar), helium (He), or a mixture thereof.

In at least one aspect, the one or more substrate preheating modules are installed on a side of the EFEM in vertical or horizontal manner.

In accordance with another embodiment there may be provided, a method of operating an equipment front end module (EFEM), comprises: providing an EFEM having an equipment front end module chamber equipped with a loading robot and one or more attached substrate preheating modules; loading substrates into the substrate preheating modules; opening a first valve to let a first gas flow into the substrate preheating modules; turning on heaters installed in the substrate preheating modules; and unloading the substrates from the substrate preheating modules.

In at least one aspect, the method further comprises: opening a second valve to pump out the first gas out of the substrate preheating modules.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a system overview of the process modules, load lock chamber, equipment front end module (EFEM) and a substrate preheating module according to an embodiment of the present disclosure.

FIG. 2 illustrates a side view of the EFEM and two substrate preheating modules attached to a side of the EFEM according to an embodiment of the present disclosure.

FIG. 3 illustrates a detailed overview of the substrate preheating module according to an embodiment of the present disclosure.

FIG. 4 illustrates a flowchart of the method to operate the EFEM with a substrate preheating module.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

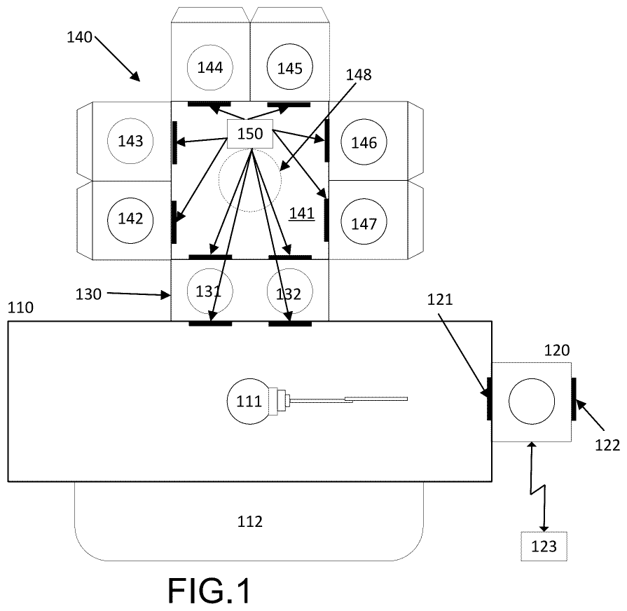

FIG. 1 illustrates a system overview of the process modules, load lock chamber, equipment front end module (EFEM) and a substrate preheating module according to an embodiment of the present disclosure.

In FIG. 1, an EFEM 110 with a robot 111 and a substrate preheating module 120 may be shown. The robot 111 may be configured to move substrates between a substrate carrier 112, a substrate preheating module 120, and a load lock chamber 130. Also, a substrate processing module 140 with a plurality of reaction chambers 142, 143, 144, 145, 146, 147 and a transfer chamber 141 may be disposed next to the load lock chamber 130. The transfer chamber 141 may comprise a transfer robot 148. In addition, the load lock chamber 130 may comprise a plurality of load lock ports 131, 132. Though not illustrated, one or more load ports may be provided between the EFEM 110 and the substrate carrier 112.

A plurality of ports 150 close or open to seal the chambers 142˜147 respectively or to let the substrates go into/out of the chambers 142˜147.

The substrate preheating module 120 may be attached to the one side of the EFEM 110. A port 121 would be for getting substrates from the EFEM 110 for preheating the substrates or for taking substrates into the EFEM 110 and into the substrate processing module 140 for processing the preheated substrates. Another port 122 may be placed on the opposite side of the port 121 for maintenance and operator manual operations.

Substrates may be carried by the substrate carrier 112 and may move into the EFEM 110, the substrate preheating module 120, and into the load lock chambers 131, 132 and finally into the reaction chambers 142˜147. The processed substrates in the chambers 142˜147 may move back to the load lock chambers 131, 132 and to the EFEM 110.

The substrates may be preheated in the substrate preheating module 120 before go into the reaction chambers 142˜147.

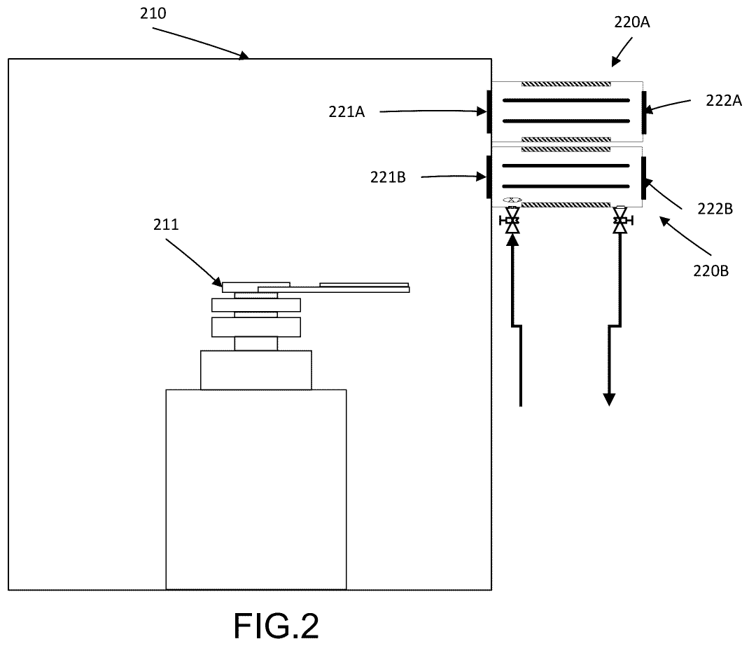

FIG. 2 illustrates a side view of the EFEM 210 and two substrate preheating modules 220A, 220 B attached to one side of the EFEM 210.

As can be seen in FIG. 2, there may be more than one substrate preheating modules 220A, 220B that may be attached to the EFEM 210. The robot arm 211 disposed in the EFEM 210 may be used to move substrates between the EFEM 210 and one of the substrate preheating modules 220A, 220B. The ports 221A, 221B may be used when substrates may move between the EFEM 210 and the substrate preheating modules 220A, 220B respectively.

Although the two substrate preheating modules 220A, 220B may be positioned vertically in FIG. 2, the substrate preheating modules 220A, 220B may also be positioned horizontally for meeting system requirements and more than one substrate preheating modules may be installed on the side of the EFEM 210.

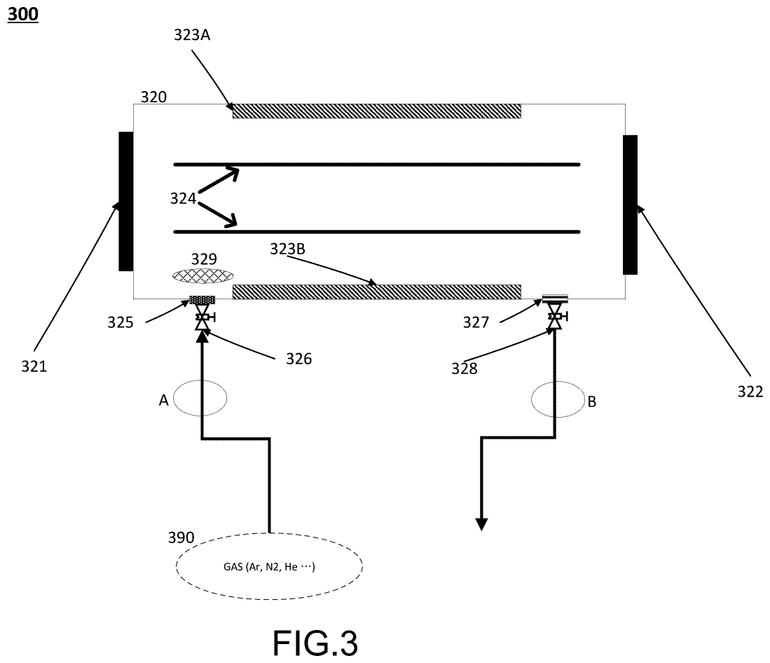

FIG. 3 illustrates the detailed view of a substrate preheating module according to an embodiment of the present disclosure.

The substrate preheating module 300 may have a chamber 320 configured to receive a substrate 324 from an EFEM. The substrate 324 may be placed vertically inside of the chamber 320 through a first opening 321 which may be docked to the EFEM. A second opening 322 may be placed on the opposite side of the first opening 321 and this second opening 322 may be used by operators for maintenance and calibration.

For preheating the substrates, the substrate preheating module 120 according to the present disclosure may use gas for heating the substrates. The gas may come from an outer gas source 390 through a gas pipe A. A first valve 326 may be placed at a mouth of a gas hole 325 which may be used to let the gas for heating the substrates into the chamber 320. For efficient substrates heating, the gas may need to be distributed inside the chamber 320 evenly so a baffle 329 may be placed right in front of the gas hole 325 for dispersing the gas more efficiently. The gas for heating the substrates may comprise one of argon (Ar), nitrogen (N₂), helium (He), or a mixture thereof. The gas for heating the substrates may be purged from the chamber 320 through an exhaust vent 327. A second valve 328 may be installed at the exhaust vent 327 and used to let the gas out of the chamber 320.

The heater may comprise more than two heating units (323A, 323B). First heating unit 323 A may be placed just below the upside wall of the chamber 320. And second heating unit 323B may also be placed just above the downside wall of the chamber 320. Therefore, each heater may face a substrate 324, enabling the heating units 323A, 323B to heat up the substrate 324 by a direct radiation and by heating up the gas. The heater may be an ultra-violet (UV) lamp or an excimer laser or any other heating mechanism to heat up the substrates directly with radiation and indirectly by heating up the gas.

The controller 123 in FIG. 1 may be electrically coupled to the substrate preheating module 120, more particularly to the first and second valves 326, 328 and the heating units 323A 323B so that the controller 123 may be configured to control the open and close of the first and second valves 326, 328 and also configured to control the turning on and off of the heating units 323A, 323B.

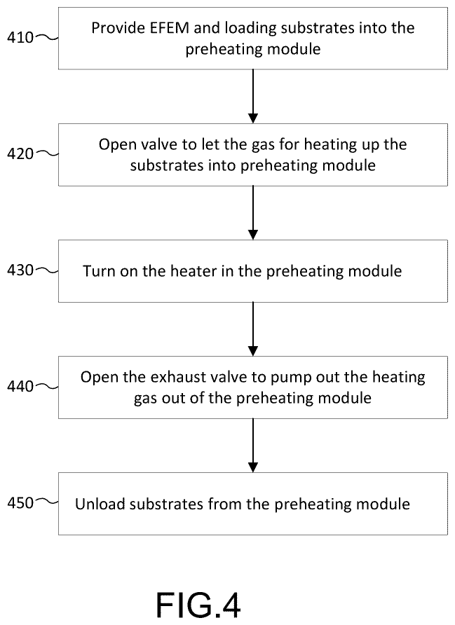

The way to operate the EFEM with a substrate preheating module may be illustrated in FIG. 4.

In the beginning in a step 410 of the method, an EFEM with a substrate preheating module is provided and substrates are to be loaded in the preheating module. Next, in a step 420 of the method, a first valve is to be opened to let the gas for heating up the substrates into the preheating module.

In a step 430 of the method, the heater may be turned on for heating up the substrates and the gas too in the preheating module. And in the final step 450 of the method, the preheated substrates may be unloaded from the preheating module. However, in a step 440 of the method, the second (exhaust) value may be opened for pumping out the heating gas from the preheating module. This step 440 may or may not be executed due to the system requirement.

With the UV lamps and/or laser heaters, the substrates may be heated up to 500 degrees Celsius. Moreover, the substrate preheating module according to the present disclosure may heat up more than one wafer and substrates may be preheated rapidly in a controlled ambient with specific gas (He/Ar/N₂) or mixture of gases outside of vacuum environment.

As can be seen in FIG. 2, the substrate preheating module according to the present disclosure may be scaled up since it can be modular and may be installed on a side of the EFEM more than one vertically or horizontally.

The above-described arrangement of system and method are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A substrate preheating module, comprising:
a chamber configured to receive more than one substrates from an equipment front end module (EFEM);
a first opening disposed on a wall of the chamber adjacent to the EFEM;
a gas inlet configured to deliver a gas from an outer gas source into the chamber;
a first valve disposed at the gas inlet and configured to control an input of the gas into the chamber;
an exhaust vent configured to pump out the gas from the chamber;
a second valve disposed at the exhaust vent and configured to control an exhaust of the gas from the chamber; and
a heater configured to heat the gas in the chamber.

2. The substrate preheating module according to claim 1, further comprising:
a controller electrically coupled to the chamber, the first valve, the second valve and the heater and configured to control an opening/closing of the first and second valve, and a turning on/off of the heater.

3. The substrate preheating module according to claim 1, further comprising:
a baffle disposed at a mouth of the gas inlet.

4. The substrate preheating module according to claim 1, further comprising:
a second opening disposed on opposite side of the first opening for maintenance.

5. The substrate preheating module according to claim 1, wherein the heater comprises at least two heating units and the heating units are disposed at least on a upside wall and on a downside wall of the chamber.

6. The substrate preheating module according to claim 1, wherein the heater comprises an ultra-violet (UV) lamps or an excimer laser.

7. The substrate preheating module according to claim 1, wherein the gas comprises at least one of nitrogen (N₂), argon (Ar), helium (He), or a mixture thereof.

8. The substrate preheating module according to claim 1, wherein the EFEM is configured to move and provide substrates for preheating and processing.

9. A device processing assembly, comprising:
an equipment front end module (EFEM) including an equipment front end module chamber having one or more interface openings and a robot arm for moving substrates;
a load lock chamber;
a plurality of processing chambers configured to process the substrates; and
one or more substrate preheating modules attached to a side of the EFEM, each of the one or more substrate preheating modules comprising:
a chamber configured to receive the substrates from the EFEM;
a first opening disposed on a wall of the chamber adjacent to the EFEM;
a gas inlet configured to deliver a gas from an outer gas source into the chamber;
a first valve disposed at the gas inlet and configured to control an input of the gas into the chamber;
an exhaust vent configured to pump out the gas from the chamber;
a second valve disposed at the exhaust vent and configured to control an exhaust of the gas from the chamber; and
a heater configured to heat the gas in the chamber.

10. The device processing assembly according to claim 9, each of the one or more substrate preheating modules further comprising:
a controller electrically coupled to the preheating module and configured to control an opening/closing of the first and second valve, and a turning on/off of the heater.

11. The device processing assembly according to claim 9, each of the one or more substrate preheating modules further comprising:
a baffle disposed at a mouth of the gas inlet.

12. The device processing assembly according to claim 9, each of the one or more substrate preheating modules further comprising:
a second opening disposed on opposite side of the first opening.

13. The device processing assembly according to claim 9, wherein for each of the one or more substrate preheating modules, the heater comprises at least two heating units and the heating units are disposed at least on an upside wall and on a downside wall of the chamber.

14. The device processing assembly according to claim 13, wherein the heater in each of the one or more substrate preheating modules comprises an ultra-violet (UV) lamps or an excimer laser.

15. The device processing assembly according to claim 9, wherein the gas comprises at least one of nitrogen (N₂), argon (Ar), helium (He), or a mixture thereof.

16. The device processing assembly according to claim 9, wherein the one or more substrate preheating modules are installed on one side of the EFEM in vertical or horizontal manner.

17. A method of operating an equipment front end module (EFEM), comprises:
providing an EFEM having an equipment front end module chamber equipped with a loading robot and one or more attached substrate preheating modules;
loading substrates into the one or more attached substrate preheating modules;
opening a first valve to let a gas flow into the one or more attached substrate preheating modules;
turning on heaters installed in the one or more attached substrate preheating modules; and
unloading the substrates from the one or more attached substrate preheating modules.

18. The method according to the claim 17, further comprises:
opening a second valve to pump the gas out of the one or more attached substrate preheating modules.

19. The method according to claim 17, wherein the gas comprises at least one of nitrogen (N₂), argon (Ar), helium (He), or a mixture thereof.

20. The method according to claim 17, wherein the heaters installed in the one or more attached substrate preheating modules comprises an ultra-violet (UV) lamps or an excimer laser.
